(19) United States
(12) Patent Application Publication
(10) Pub. No.: US 2026/0243702 A1
(43) Pub. Date: Aug. 20, 2026

(54) DEFECT INSPECTION DEVICE AND DEFECT INSPECTION METHOD

(71) Applicant: HITACHI HIGH-TECH CORPORATION, Minato-ku, Tokyo (JP)

(72) Inventors: Yuta URANO, Tokyo (JP); Hiromichi YAMAKAWA, Tokyo (JP); Eiji ARIMA, Tokyo (JP); Toshifumi HONDA, Tokyo (JP)

(21) Appl. No.: 19/156,058

(22) PCT Filed: Mar. 1, 2023
(86) PCT No.: PCT/JP2023/007497

§ 371 Date: Aug. 13, 2025

(51) Int. Cl. G01N 21/956; G01N 21/88

(52) U.S. Cl. CPC G01N 21/95684; G01N 21/8806; G01N 2021/8809

(57) ABSTRACT

A defect inspection device is provided including: a stage on which a sample is to be placed and moved; an illumination optical system configured to irradiate the sample with illumination light; a detection optical system configured to detect scattered light generated at the sample by forming an image of the scattered light on an image sensor; a control device configured to control the stage; and a signal processing device configured to process a signal output from the image sensor. The signal processing device stores detection signals obtained by scanning a predetermined region of interest on a surface of the sample a plurality of times along a scanning trajectory that has a shift amount of a non-integer multiple of a pixel pitch of the image sensor, estimates intensity distributions of the detection signals of the object in the region of interest in a plurality of scans, detects a shift amount of the scanning trajectory based on the intensity distributions, and aligns and synthesizes the intensity distributions in the plurality of scans based on the detected shift amount, and acquires a point spread function related to the object in a sub-pixel unit having a data interval smaller than the pixel pitch.

### TECHNICAL FIELD

The present invention relates to a defect inspection device and a defect inspection method.

### BACKGROUND ART

For example, in a manufacturing process for a substrate such as a semiconductor or a flat panel display, a defect on a surface of the substrate is inspected. As a device used for such inspection, there is a dark-field optical defect inspection device that obliquely illuminates a surface of a sample (substrate), detects scattered light from a defect by an imaging detection optical system, and inspects the defect (PTL 1).

### CITATION LIST

### Patent Literature

PTL 1: JP2014-174052A

### SUMMARY OF INVENTION

### Technical Problem

In the dark-field optical defect inspection device employing an imaging detection optical system, fine focus adjustment of the optical system is required to stably obtain high inspection sensitivity. In PTL 1, when adjusting positions of an illumination optical system and the detection optical system, an adjustment substrate on which a plurality of repetitive patterns for generating scattered light are formed is used. However, in a defect inspection device that irradiates a sample with high-power illumination light to inspect minute defects with high sensitivity, when the illumination light is irradiated to a stationary adjustment substrate as in the same document, the adjustment substrate is damaged and deteriorated, becoming useless. Therefore, it is difficult to detect the scattered light and finely adjust the focus under the same high-power illumination condition as that in the actual inspection of the sample.

In a defect inspection device that uses a low-magnification detection optical system and inspects a sample at high speed under a condition in which a pixel size of a detection sensor converted onto the sample is large, since resolution for measuring a spread width of a detected image is low, it is difficult to perform precise focus adjustment.

An object of the invention is to provide a defect inspection device and a defect inspection method capable of precisely performing focus adjustment of a detection optical system and stably maintaining high inspection sensitivity.

### Solution to Problem

In order to achieve the above object, the invention provides a defect inspection device including: a stage on which a sample is to be placed and moved; an illumination optical system configured to irradiate the sample with illumination light; a detection optical system configured to defect scattered light generated at the sample by forming an image of the scattered light on an image sensor; a control device configured to control the stage; and a signal processing device configured to process a signal output from the image sensor. The signal processing device stores detection signals obtained by scanning a predetermined region of interest on a surface of the sample a plurality of times along a scanning trajectory that has a shift amount of a non-integer multiple of a pixel pitch of the image sensor, estimates intensity distributions of the detection signals of the object in the region of interest in the plurality of scans, detects a shift amount of the scanning trajectory based on the intensity distributions, and aligns and synthesizes the intensity distributions in the plurality of scans based on the detected shift amount, and acquires a point spread function related to the object in a sub-pixel unit having a data interval smaller than the pixel pitch.

### Advantageous Effects of Invention

According to the invention, the focus adjustment of a detection optical system can be precisely performed, and the high inspection sensitivity can be stably maintained.

### BRIEF DESCRIPTION OF DRAWINGS

FIG. 1 is a schematic diagram of a defect inspection device according to an embodiment of the invention.

FIG. 2 is a schematic diagram illustrating an example of a scanning trajectory on a sample.

FIG. 3 is a schematic diagram illustrating another example of the scanning trajectory on the sample.

FIG. 4 is a schematic diagram illustrating a relationship between an optical axis of illumination light guided to a sample surface from an oblique direction by an illumination optical system and an illumination intensity distribution shape.

FIG. 5 is a schematic diagram illustrating a relationship between the optical axis of the illumination light guided to the sample surface from an oblique direction by the illumination optical system and an illumination intensity distribution shape.

FIG. 6 is a schematic diagram illustrating a configuration of a detection optical system (inclined optical system) provided in the defect inspection device.

FIG. 7 is a schematic diagram illustrating a configuration of a detection optical system (inclined optical system) provided in the defect inspection device.

FIG. 8 is a schematic diagram illustrating a configuration of a detection optical system (vertical optical system) provided in the defect inspection device.

FIG. 9 is a view taken along a line X-X in the detection optical system (vertical optical system).

FIG. 10 is illustrative diagram an illustrating a principle of measuring a height variation of a sample surface by a height measuring unit.

FIG. 11 is a schematic diagram of a three-dimensional arrangement of the sample and the inclined optical system.

FIG. 12 is a diagram illustrating a standard particle dispersed sample and a scanning trajectory for measuring a point spread function of each detection optical system.

FIG. 13 is a diagram illustrating extracted functional blocks of a signal processing device that acquires a point spread function.

FIG. 14 is a block diagram illustrating processing content of sub-pixel interpolation processing.

FIG. 15 is a graph illustrating an example of setting and operation for stage scanning.

FIG. 16 is a diagram illustrating another example of setting and operation for stage scanning.

FIG. 17 is a schematic diagram illustrating a principle of sub-pixel interpolation processing.

FIG. 18 is a schematic diagram illustrating an evaluation method of a detection signal in particle signal measurement.

FIG. 19 is a schematic diagram of an operation screen displaying a result of the particle signal measurement.

FIG. 20 is a schematic diagram illustrating a position shift direction of a point image on an image sensor due to a sample surface height shift.

FIG. 21 is a schematic diagram illustrating a position shift direction of a point image on the image sensor due to an illumination spot position shift in an S1 direction.

FIG. 22 is a diagram illustrating an example of a method of adjusting the illumination optical system and the detection optical system.

FIG. 23 is a flowchart illustrating an adjustment procedure for the detection optical system.

### DESCRIPTION OF EMBODIMENTS

Hereinafter, embodiments of the invention will be described with reference to the drawings.

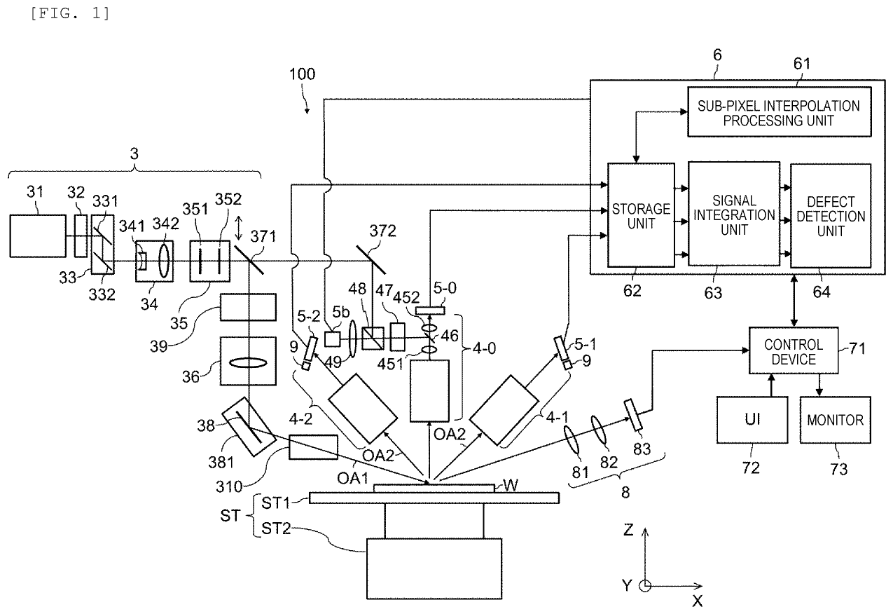

FIG. 1 is a schematic diagram of a defect inspection device 100 according to an embodiment of the invention.

The defect inspection device 100 according to the embodiment takes a sample W as an object to be inspected, and detects a defect such as a foreign matter or a recess on a surface (hereinafter, referred to as a sample surface) of the sample W, particularly, a defect of a type corresponding to an inspection purpose. As the sample W, for example, a circular plate-shaped semiconductor silicon wafer having a flat surface on which no pattern is formed is given as a representative example. The defect inspection device 100 includes a stage ST, an illumination optical system 3, detection optical systems 4-0, 4-1, 4-2, etc., a height measuring unit 8, a signal processing device 6, a control device 71, a user interface 72 such as a mouse and a keyboard, and a monitor 73 as a display unit.

The signal processing device 6 and the control device 71 are computers equipped with a central processing unit (CPU) and a memory, and control a focus actuator (an actuator 9 described later in the embodiment) according to an output of the height measuring unit 8. The signal processing device 6 and the control device 71 may be implemented by different computers, or may be implemented by a single computer. Both the signal processing device 6 and the control device 71 can be implemented by a plurality of computers connected via a network.

The stage ST is a device for placing and moving the sample W, and includes a sample stage ST1 and a scanning device ST2. The sample stage ST1 is a stage that supports the sample W. The scanning device ST2 is a device that drives the sample stage ST1 to change a relative position between the sample W and the illumination optical system 3. The scanning device ST2 includes a translation stage, a rotation stage, and a Z stage. The rotation stage is supported by the translation stage via the Z stage, and the sample stage ST1 is supported by the rotation stage. The translation stage performs a translational movement in a horizontal direction together with the rotation stage, and the rotation stage rotates about an axis extending vertically. The Z stage functions to adjust a height of a sample surface. In FIG. 1, a Z direction is an upper side of the paper, an X direction is a right side of the paper, and a Y direction is a front side of the paper.

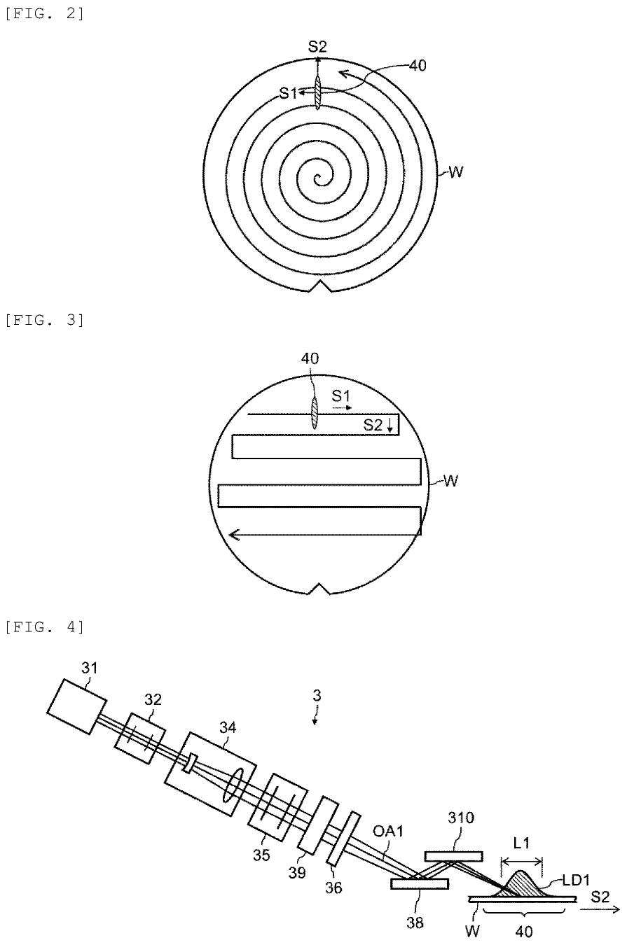

FIG. 2 is a schematic diagram illustrating an example of a scanning trajectory on the sample W by the scanning device ST2. As will be described later, an illumination spot 40 formed on the sample surface by illumination light emitted from the illumination optical system 3 has an illumination intensity distribution long in one direction as illustrated in FIG. 2. A major axis direction of the illumination spot 40 (a radial direction of the sample stage ST1) is defined as a direction S2, and a direction substantially orthogonal to the major axis (a circumferential direction around a rotation axis of the sample stage ST1) is defined as a direction S1. An arrow in FIG. 2 indicates a scanning trajectory on the sample W.

The sample W is rotated with the rotation of the rotation stage, and scanning is performed d with the illumination spot 40 in the direction S1 relative to the sample surface. Further, the sample W is moved in the horizontal direction with the translation of the translation stage, and the scanning is performed with the illumination spot 40 in the direction S2 relative to the sample surface. When the sample W performs a translational movement while being rotated by an operation of the scanning device ST2, as illustrated in FIG. 2, the illumination spot 40 moves presenting a spiral trajectory from a center to an outer edge of the sample W, and the entire surface of the sample surface is scanned. The illumination spot 40 moves in the direction S2 by a distance equal to or less than a length of the illumination spot 40 in the direction S2 during one rotation of the sample W.

A configuration in which another translation stage whose movement axis extends in a direction intersecting a movement axis of the translation stage in a horizontal plane is provided instead of the rotation stage can also be applied to the scanning device ST2. In this case, as illustrated in FIG. 3, the sample surface is scanned with the illumination spot 40 in a folded linear trajectory instead of the spiral trajectory. An arrow in FIG. 3 indicates the scanning trajectory on the sample W.

Arrows in FIG. 3 indicate that a first translation stage is translationally driven in the direction S1 at a constant speed, a second translation stage is driven in the direction S2 by a predetermined distance (for example, a distance equal to or less than the length of the illumination spot 40 in the direction S2), and then the first translation stage turns back in the direction S1 again to be translationally driven. Accordingly, the entire surface of the sample surface is scanned with the illumination spot 40 by repeating linear scanning in the direction S1 and movement in the direction S2. Compared with this scanning method, since the spiral scanning method illustrated in FIG. 2 does not involve a reciprocating operation, the spiral scanning method is advantageous in inspecting the sample W in a short time.

Returning to the description of FIG. 1. The illumination optical system 3 illustrated in FIG. 1 is an optical unit including a plurality of optical elements for irradiating the sample W placed on the sample stage ST1 with desired illumination light, and forms, on the sample surface, the illumination spot 40 that is long in one direction (direction S2) to have a major axis.

As illustrated in FIG. 1, the illumination optical system 3 includes a laser light source 31, an attenuator 32, an emitted light adjustment unit 33, a beam expander 34, a polarization control unit 35, an anamorphic beam expander 39, a cylindrical lens 36, an anamorphic condenser mirror 310, reflection mirrors 371, 372, and 38, and the like.

The laser light source 31 is a unit that emits a laser beam as illumination light. A diameter of the laser beam emitted from the laser light source 31 is typically about 1 mm. When detecting a minute defect in the vicinity of the sample surface by the defect inspection device 100, a light source that oscillates a high-power laser beam having an output of 2 W or more is used for the laser light source 31, the laser beam being ultraviolet or vacuum ultraviolet having a short wavelength (for example, a wavelength of 355 nm or less) that hardly penetrates into the sample W. Although in the embodiment, for example, a laser beam having a wavelength of 266 nm is applied, a laser beam having a wavelength according to the purpose can be used from near ultraviolet rays having a wavelength of 200 nm to 380 nm or vacuum ultraviolet rays having a wavelength of 10 nm to 200 nm. When detecting a defect inside the sample W by the defect inspection device 100, a light source that oscillates a visible or infrared laser beam having a long wavelength and easily penetrating into the sample W is used for the laser light source 31.

The emitted light adjustment unit 33 is a unit that adjusts an angle of an optical axis of the illumination light attenuated by the attenuator 32 and includes a plurality of reflection mirrors 331 and 332 in the embodiment. Although the illumination light is sequentially reflected by the reflection mirrors 331 and 332, in the embodiment, a plane of incidence and emission of the illumination light with respect to the reflection mirror 331 is orthogonal to a plane of incidence and emission of the illumination light with respect to the reflection mirror 332.

The plane of incidence and emission is a plane including an optical axis incident on a reflection mirror and an optical axis emitted from the reflection mirror. For example, when a three-dimensional XYZ orthogonal coordinate system different from the XYZ coordinate system in FIG. 1 is defined and the illumination light is incident on the reflection mirror 331 in a +X direction, the illumination light is, for example, deflected by the reflection mirror 331 in a +Y direction and then deflected by the reflection mirror 332 in a +Z direction. In this example, the plane of incidence and emission of the illumination light with respect to the reflection mirror 331 is an XY plane, and the plane of incidence and emission with respect to the reflection mirror 332 is a YZ plane.

The reflection mirrors 331 and 332 are provided with mechanisms (not shown) for causing the reflection mirrors 331 and 332 to perform a translational movement and tilt. The reflection mirrors 331 and 332 perform a translational movement in, for example, an incident direction or an emission direction of the illumination light with respect to the reflection mirrors 331 and 332, and tilt around a normal line to the planes of incidence and emission thereof. Accordingly, for example, with respect to an optical axis of the illumination light emitted in the +Z direction from the emitted light adjustment unit 33, an offset amount and an angle in an XZ plane and an offset amount and an angle in a YZ plane can be independently adjusted. Although a configuration using two reflection mirrors 331 and 332 is illustrated in the embodiment, a configuration using three or more reflection mirrors may be adopted.

The beam expander 34 is a unit that enlarges a beam diameter of incident illumination light and includes a plurality of lenses 341 and 342. An example of the beam expander 34 is a Galileo type using a concave lens as the lens 341 and a convex lens as the lens 342. The beam expander 34 is provided with an interval adjustment mechanism (zoom mechanism) for the lenses 341 and 342, and an enlargement ratio of the beam diameter is changed by adjusting an interval between the lenses 341 and 342.

The enlargement ratio of the beam diameter by the beam expander 34 is about 2 times to 5 times, and in this case, when the beam diameter of the illumination light emitted from the laser light source 31 is 1 mm, the beam diameter of the illumination light is enlarged to about 2 mm to 5 mm. When the illumination light incident on the beam expander 34 is not a parallel beam, the illumination light can be collimated (quasi-parallelization of the beam) together with the beam diameter by adjusting the interval between the lenses 341 and 342. Alternatively, the beam may be collimated by a collimating lens that is provided upstream of the beam expander 34 and separately from the beam expander 34.

The anamorphic beam expander 39 is a unit that enlarges the beam diameter of the illumination light in one direction. Examples of the anamorphic beam expander 39 include an anamorphic prism pair formed by combining a plurality of prisms and a cylindrical beam expander formed by combining a plurality of cylindrical lenses. By the anamorphic beam expander 39, the beam diameter of the illumination light in a direction corresponding to the S1 direction on the sample W is enlarged to about 3 times to 15 times, and becomes about 15 mm to 30 mm.

The polarization control unit 35 is an optical system that controls a polarization state of the illumination light and includes a half-wavelength plate 351 and a quarter-wavelength plate 352. For example, when performing oblique incidence illumination by placing the reflection mirror 371 in an optical path, which will be described later, the amount of scattered light from a defect on the sample surface is increased by setting the illumination light to be P-polarized light by the polarization control unit 35, as compared with polarized light other than the P-polarized light. When scattered light (referred to as haze) from minute unevenness on the sample surface obstructs the detection of a minute defect, the illumination light is set to S-polarized light, so that the haze can be reduced as compared with polarized light other than the S-polarized light. The polarization control unit 35 can also set the illumination light to be circularly polarized light or to be 45° polarized light between the P-polarized light and S-polarized light.

The cylindrical lens 36 is a unit that condenses the illumination light in the direction S2 on the sample W to adjust a size of the illumination spot 40 in a longitudinal direction.

The anamorphic condenser mirror 310 is a unit that has a curvature in a direction corresponding to the direction S1 on the sample W and condenses the illumination light in the direction S1 on the sample W to adjust a size of the illumination spot 40 in a lateral direction. The anamorphic condenser mirror 310 is a condensing element that condenses irradiation light of the laser at an irradiation position on a sample stage surface from an angle inclined with respect to a normal line of the sample stage surface. The anamorphic condenser mirror 310 has no curvature in a direction orthogonal to the direction S1 on the sample W. A curved surface of the anamorphic condenser mirror 310 in the direction S1 on the sample W is an aspherical surface for reducing a spherical aberration, and specifically, is an optimum parabolic surface for condensing collimated incident light.

As indicated by arrows in FIG. 1, the reflection mirror 371 can get in and out of the optical path of the illumination light that travels toward the sample W by performing a translational movement by a drive mechanism (not shown), thereby switching incident paths of the illumination light onto the sample W. By inserting the reflection mirror 371 into the optical path, the illumination light emitted from the polarization control unit 35 is reflected by the reflection mirror 371, and is obliquely incident on the sample W via the anamorphic beam expander 39, the cylindrical lens 36, the reflection mirror 38, and the anamorphic condenser mirror 310. On the other hand, when the reflection mirror 371 is removed from the optical path, the illumination light emitted from the polarization control unit 35 is perpendicularly incident on the sample W via the reflection mirror 372, a polarized beam splitter 48, a polarization control unit 47, a reflection mirror 46, and the detection optical system 4-0.

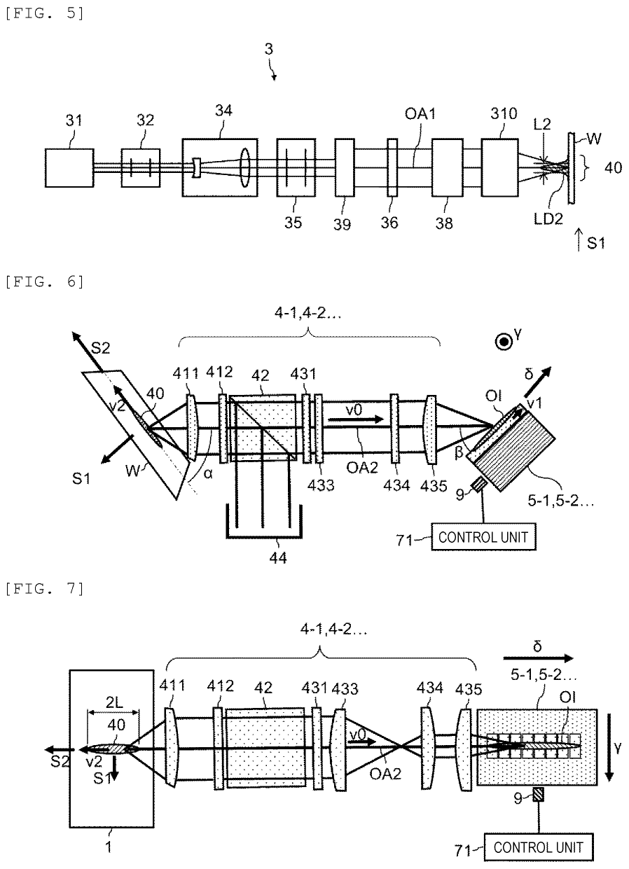

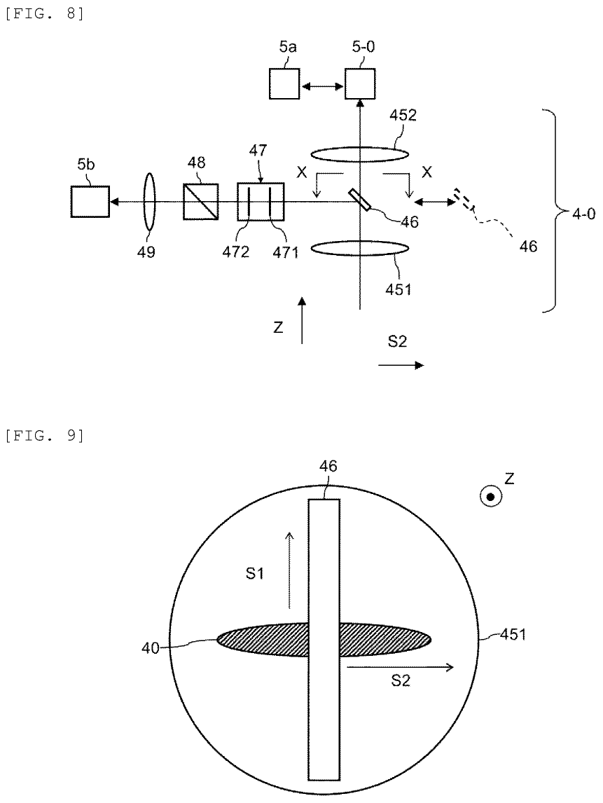

FIGS. 4 and 5 are schematic diagrams illustrating relationships between an optical axis OA1 of the illumination light guided to the sample surface from an oblique direction by the illumination optical system 3 and an illumination intensity distribution shape. FIG. 4 schematically illustrates a cross section of the sample W taken along a plane of incidence of the illumination light incident on the sample W. FIG. 5 schematically illustrates a cross section of the sample W taken along a plane, the plane being perpendicular to the plane of incidence of the illumination light incident on the sample W and including a normal line to the sample surface. The plane of incidence is a plane including the optical axis OA1 of the illumination light incident on the sample W and the normal line to the sample surface. In FIGS. 4 and 5, a part of the illumination optical system 3 is extracted and illustrated. For example, the emitted light adjustment unit 33 and the reflection mirrors 371, 372, and 38 are not illustrated.

When the reflection mirror 371 is inserted into the optical path, the illumination light emitted from the laser light source 31 is condensed by the cylindrical lens 36 to be adjusted to have a desired intensity distribution, reflected by the reflection mirror 38, and obliquely incident on the sample W. In this way, the illumination optical system 3 is configured such that the illumination light can be incident on the sample W from an inclined direction relative to the normal line to the sample surface. In the oblique incidence illumination, the light intensity is adjusted by the attenuator 32, the beam diameter is adjusted by the beam expander 34, the polarization is adjusted by the polarization control unit 35, and the intensity distribution is adjusted by the cylindrical lens 36, so that the illumination intensity distribution becomes a Gaussian distribution in the plane of incidence. As in an illumination intensity distribution (illumination profile) LD1 illustrated in FIG. 4, the illumination spot 40 formed on the sample W has a Gaussian illumination intensity distribution in the direction S2. A beam width L1 in the direction S2 defined by 13.5% of a peak is, for example, about 25 μm to 800 μm.

In a plane orthogonal to the plane of incidence and the sample surface, the illumination spot 40 has a light intensity distribution in which an intensity in the periphery is weaker as compared with an intensity at a center of the beam as in an illumination intensity distribution (illumination profile) LD2 illustrated in FIG. 5. Specifically, the intensity distribution is a Gaussian distribution reflecting the intensity distribution of the light incident on the anamorphic condenser mirror 310, or an intensity distribution similar to the Bessel function of the first kind of order 1 or sinc function reflecting an aperture shape of the anamorphic condenser mirror 310.

A width L2 of the illumination intensity distribution in the plane orthogonal to the plane of incidence and the sample surface is set to be narrower than the beam width L1 illustrated in FIG. 4, and is set to, for example, about 1.5 μm to 10 μm in order to reduce the haze generated from the sample surface. In order to make the width L2 narrower than the beam width L1, a numerical aperture (NA) for condensing in the direction S2 is larger than an NA in the direction S1. This is because the anamorphic beam expander 39 enlarges an incident beam diameter in the condensing in the direction S2 to have a larger size than an incident beam diameter in the direction S1, and a focal distance (an optical path length of the condensed beam) is shorter in the direction S2 than in the direction S1. The width L2 of the illumination intensity distribution is a length of a region having an illumination intensity of 13.5% or more of the maximum illumination intensity in the plane orthogonal to the plane of incidence and the sample surface.

An incident angle with respect to the sample W (a tilt angle of an incidence optical axis with respect to the normal line to the sample surface) in the oblique incidence illumination is adjusted to an angle suitable for detection of a minute defect by positions and angles of the reflection mirrors 371 and 38. The angle of the reflection mirror 38 is adjusted by an adjustment mechanism 381. For example, the larger the incident angle of the illumination light with respect to the sample W (the smaller an illumination elevation angle that is an angle formed by the sample surface and the incident optical axis) is, the weaker the haze that becomes noise for scattered light from a minute foreign matter on the sample surface is, making it suitable for detecting a minute defect. From a viewpoint of reducing the influence of the haze on the detection of the minute defect, the incident angle of the illumination light is preferably set to, for example, 75 degrees or more (elevation angle of 15 degrees or less). On the other hand, in the oblique incidence illumination, since the absolute amount of scattered light from a minute foreign matter increases as the illumination incident angle decreases, it is preferable to set the incident angle of the illumination light to, for example, 60 degrees or more and 75 degrees or less (that is, the elevation angle of 15 degrees or more and 30 degrees or less) from the viewpoint of increasing the amount of scattered light from a defect.

Returning to the description of FIG. 1. The detection optical systems 4-0, 4-1, 4-2, etc. are optical units that detect scattered light, which is generated at the illumination spot 40 on the sample surface, by forming an image of the scattered light on image sensors (imaging sensors) 5-0, 5-1, 5-2, etc. and include a plurality of optical elements including a condenser lens (objective lens). The objective lenses of the detection optical systems 4-0, 4-1, 4-2, etc. are arranged along an upper hemispherical surface of a sphere (celestial sphere) centered on the illumination spot 40 on the sample W. Scattered light incident on the detection optical systems 4-0, 4-1, 4-2, etc. is condensed and guided to the respective image sensors 5-0, 5-1, 5-2, etc. In the embodiment, an optical path of the scattered light incident on the detection optical system 4-0 is branched at the reflection mirror 46, and the scattered light is guided to an image sensor 5b in addition to the image sensor 5-0.

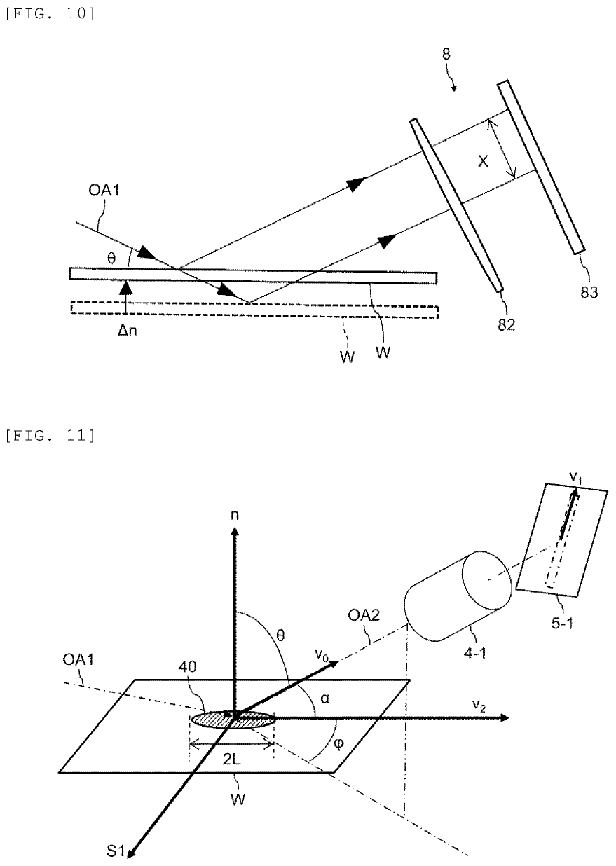

FIGS. 6 and 7 are schematic diagrams illustrating a configuration of each detection optical system 4-1, 4-2, etc. That is, FIGS. 6 and 7 are schematic diagrams of each detection optical system 4-1, 4-2, etc. in which the optical axis is inclined with respect to the sample surface. FIG. 6 schematically illustrates a cross section (viewed in a −Y direction in FIG. 1) of each detection optical system 4-1, 4-2, etc. taken along a reflection plane in which the scattered light incident on the detection optical system 4-1, 4-2, etc. is reflected by the sample W. FIG. 7 is a schematic diagram of each detection optical system 4-1, 4-2, etc. viewed from a direction intersecting the optical axis of the detection optical system 4-1, 4-2, etc. along the reflection plane (viewed in a −Z direction in FIG. 1).

The reflection plane is a plane including an optical axis OA2 of the scattered light incident on the detection optical systems 4-1, 4-2, etc. and a normal line to the sample surface. Hereinafter, the detection optical systems 4-1, 4-2, etc. whose optical axis OA2 is inclined with respect to the sample surface and the image sensors 5-1, 5-2, etc. may be abbreviated as “the detection optical systems 4-1, etc.” and “the image sensors 5-1, etc.”

As illustrated in FIGS. 6 and 7, the detection optical systems 4-1, etc. are both-side telecentric optical systems configured such that an imaging magnification does not change even when a working distance changes. The detection optical systems 4-1, etc. include a condenser lens (objective lens) 411, a half-wavelength plate 412, a polarized beam splitter 42, a half-wavelength plate 431, cylindrical lenses 433 and 434, an image forming lens 435, and the image sensors 5-1, etc. along the optical axis OA2. Illumination scattered light incident on the detection optical systems 4-1, etc. is guided to the respective image sensors 5-1, etc. The detection optical systems 4-1, etc. also include a beam diffuser 44 in a traveling direction of light split by the polarized beam splitter 42.

In the detection optical systems 4-1, etc., the condenser lens 411 condenses the illumination scattered light, and a polarization direction thereof is controlled by the half-wavelength plate 412. The half-wavelength plate 412 is rotatable by an actuator (not shown).

An optical path of light transmitting through the half-wavelength plate 412 is branched by the polarized beam splitter 42 according to the polarization. By a combination of the half-wavelength plate 412 and the polarized beam splitter 42, an optical signal indicating a defect of the sample W and an optical signal (roughness scattered light from the sample surface) hindering the defect detection of the sample W are easily separated.

Light transmitting through the polarized beam splitter 42 is controlled by the half-wavelength plate 431 to have a polarization direction suitable for detection in the image sensors 5-1, etc. On the other hand, the light branched from the optical path by the polarized beam splitter 42 is attenuated by the beam diffuser 44 so as not to become stray light.

A cross-sectional shape of the light transmitting through the half-wavelength plate 431 is adjusted by the cylindrical lenses 433 and 434. The cylindrical lenses 433 and 434 constitute a cylindrical beam expander, and a spread of an optical image OI formed on light receiving surfaces of the image sensors 5-1, etc. in a lateral direction γ is adjusted to be smaller than a spread of the optical image OI in a longitudinal direction δ. The light receiving surfaces of the image sensors 5-1, etc. coincide with each other at positions conjugate with the illumination spot 40 formed on the sample surface in the longitudinal direction d, but are not necessarily conjugate with the illumination spot 40 in the lateral direction γ. However, the lateral direction γ of the light receiving surface coincides with the lateral direction of the optical image OI, and an image height (width) of the optical image OI in the lateral direction γ is reduced by the cylindrical lenses 433 and 434, so that almost no defocus occurs in the lateral direction γ. A beam whose cross-sectional shape is adjusted by the cylindrical lenses 433 and 434 is guided to the image sensors 5-1, etc. via the image forming lens 435, and the optical image OI of the illumination spot 40 is formed on a plurality of pixels of the image sensors 5-1, etc. A detection signal of the optical image photoelectrically converted at each pixel of the image sensors 5-1, etc. is output to the signal processing device 6.

In this way, the detection optical systems 4-1, 4-2, etc. condense the scattered light of the illumination spot 40, which is formed on the sample W by the illumination optical system 3, control a polarization state of the incident scattered light, and form an optical image of the illumination spot 40 on the light receiving surfaces of the corresponding image sensors 5-1, 5-2, etc.

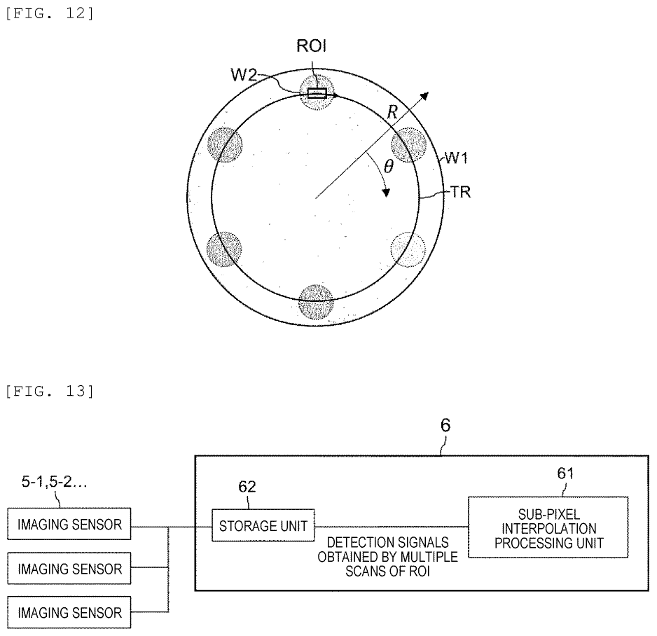

FIG. 8 is a configuration diagram of the detection optical system 4-0 on which scattered light from the sample W in a normal direction is incident, and FIG. 9 is a view taken along a line X-X in FIG. 8.

The detection optical system 4-0 includes a condenser lens (objective lens) 451 and an image forming lens 452, and guides the scattered light condensed by the condenser lens 451 to the image sensor 5-0 by the image forming lens 452.

In the detection optical system 4-0, the reflection mirror 46 is disposed at a position of its own pupil between the condenser lens 451 and the image forming lens 452. In a case of epi-illumination in which the reflection mirror 371 illustrated in FIG. 1 is removed from the optical path, the illumination light is incident on the sample W from the normal direction via the reflection mirror 46. As described above, the condenser lens 451 of the detection optical system 4-0 also serves as a condenser lens that guides epi-illumination to the sample W.

On the other hand, the reflection mirror 46 also plays a role of branching the optical path of a part of the scattered light incident on the detection optical system 4-0 from the illumination spot 40 in the oblique incidence illumination or the epi-illumination. As described above, the illumination spot 40 has a linear intensity distribution elongated in the direction S2. As illustrated in FIG. 9, when viewed from the image sensor 5-0, the reflection mirror 46 is longer than the illumination spot 40 in the direction S1 that is a minor axis direction of the linear illumination spot 40, and is shorter than the illumination spot 40 in the direction S2 that is the major axis direction of the illumination spot 40. Accordingly, scattered light that is incident on the detection optical system 4-0 from the sample W and does not interfere with the reflection mirror 46 is incident on the image sensor 5-0 via the image forming lens 452, and scattered light that interferes with the reflection mirror 46 is reflected by the reflection mirror 46.

The scattered light incident on the detection optical system 4-0 from the sample W and reflected by the reflection mirror guided to the image sensor 5b via the polarization control unit 47, the polarized beam splitter 48, and an image forming lens 49. Similarly to the polarization control unit 35, the polarization control unit 47 includes a quarter-wavelength plate 471 and a half-wavelength plate 472, and can adjust the illumination scattered light incident from the reflection mirror 46 to any polarization. The polarization control unit 47 corresponds to a polarizing element capable of switching the polarization of the irradiation light between S-polarized light (first polarization) and P-polarized light (second polarization orthogonal to the first polarization). At the time of oblique incidence illumination, the polarization of the illumination scattered light to be incident on the polarized beam splitter 48 is controlled to be linear polarization by the quarter-wavelength plate 471 of the polarization control unit 47 so that the illumination scattered light reflected by the reflection mirror 46 is transmitted through the polarized beam splitter 48 and incident on the image forming lens 49.

Returning to the description of FIG. 1. The control device 71 controls the polarization of the illumination light by the polarization control unit 47 such that the illumination light traveling toward the sample W is incident on the detection optical system 4-0 as light polarized in any direction (for example, circularly polarized light) under the condition of epi-illumination in which the reflection mirror 371 is removed from the optical path. The control device 71 functions as a control unit that controls the polarization control unit 47 such that an intensity in a set region in an intensity distribution of an optical image detected by an observation image detector is within a set range.

A sample surface sensor 5a (FIG. 8) can be installed at the position of the image sensor 5-0 or a position conjugate therewith instead of the image sensor 5-0 by a drive mechanism (not shown), and is used to observe an enlarged image of the sample surface projected by the detection optical system 4-0. The intensity distribution of the illumination spot 40 is measured by the sample surface sensor 5a, and the position and focus of the illumination spot 40 are adjusted based on the intensity distribution. In order to measure the position, width, and length of the illumination spot 40 with high accuracy, a complementary metal-oxide-semiconductor (CMOS) area sensor or a charge coupled device (CCD) area sensor having a pixel pitch smaller than that of the image sensor 5-0 is used as the sample surface sensor 5a. When performing imaging by the sample surface sensor 5a, the reflection mirror 46 is retracted from the optical path by a drive mechanism (not shown) in order not to decrease image resolution.

The image sensors 5-0, 5-1, 5-2, etc. are line sensors each having a light receiving surface in which a plurality of pixels are arranged in a line (in an array), and correspond to the detection optical systems 4-0, 4-1, 4-2, etc., respectively. A CMOS imaging element or a CCD imaging element is used for the image sensors 5-0, 5-1, 5-2, etc. The detection optical systems 4-0, 4-1, 4-2, etc. form the optical image OI of the illumination spot 40 on the light receiving surfaces of the corresponding image sensors 5-0, 5-1, 5-2, etc. The image sensors 5-0, 5-1, 5-2, etc. photoelectrically convert the optical image OI formed on the light receiving surfaces, perform predetermined sampling, convert an analog electrical signal into digital data, and output the digital data to the signal processing device 6 as a data set of a scattered light intensity of the optical image OI.

In the embodiment, the light receiving surfaces of the image sensors 5-1, 5-2, etc. are inclined with respect to the optical axis OA2 according to the inclination of the optical axis OA2 of the corresponding detection optical systems 4-1, 4-2, etc. with respect to the sample surface, and major axes of the light receiving surface coincide with each other at positions conjugate with the illumination spot 40 formed on the sample surface. However, the image sensor 5-0 facing the illumination spot 40 in the normal direction of the sample surface is excluded. The light receiving surface of the image sensor 5-0 is orthogonal to the optical axis OA2 of the detection optical system 4-0. Each of the image sensors 5-1, 5-2, etc. is arranged such that the major axis (center line extending in the longitudinal direction) of the light receiving surface and a major axis of the optical image OI (FIG. 6) of the illumination spot 40 are parallel to each other, and the entire illumination spot 40 falls within a one-dimensional light receiving surface constituted by arranging pixels in an array.

Further, in the defect inspection device 100 illustrated in FIG. 1, the actuator 9 for moving the image sensors 5-1, 5-2, etc. is provided for each of the image sensors 5-1, 5-2, etc. As the actuator 9, for example, a piezo actuator can be used, the corresponding sensor can be shifted with good response, and the corresponding sensor can be three-dimensionally translated, for example. In the embodiment, the actuator 9 serves as a focus actuator that moves an in-focus position of the optical image in the detection optical system corresponding to the actuator 9 relative to the light receiving surfaces of the corresponding image sensors 5-1, 5-2, etc.

A part of the scattered light condensed by the detection optical system 4-0 is guided to the image sensor 5b in addition to the image sensor 5-0. As the image sensor 5b, a two-dimensional CCD imaging element, a two-dimensional CMOS imaging element, or a two-dimensional position sensing detector (PSD) is used. The image sensor 5b also photoelectrically converts an optical image obtained by condensing in the detection optical system 4-0, performs predetermined sampling, converts an electrical signal into digital data by analog/digital conversion, and outputs the digital data to the signal processing device 6.

The height measuring unit 8 illustrated in FIG. 1 is a unit for measuring a height of the illumination spot 40 on the sample surface, and includes a condenser lens 81, an image forming lens 82, and a two-dimensional sensor 83. As the two-dimensional sensor 83, a two-dimensional CCD imaging element, a two-dimensional CMOS imaging element, or a two-dimensional position sensing detector (PSD) is used. The two-dimensional sensor 83 photoelectrically converts the optical image OI that is formed on the light receiving surface by the condenser lens 81 and the image forming lens 82, converts an electrical signal into digital data by analog/digital conversion, and outputs the digital data to the control device 71. The output of the height measuring unit 8 may be input to the signal processing device 6 and input to the control device 71 via the signal processing device 6.

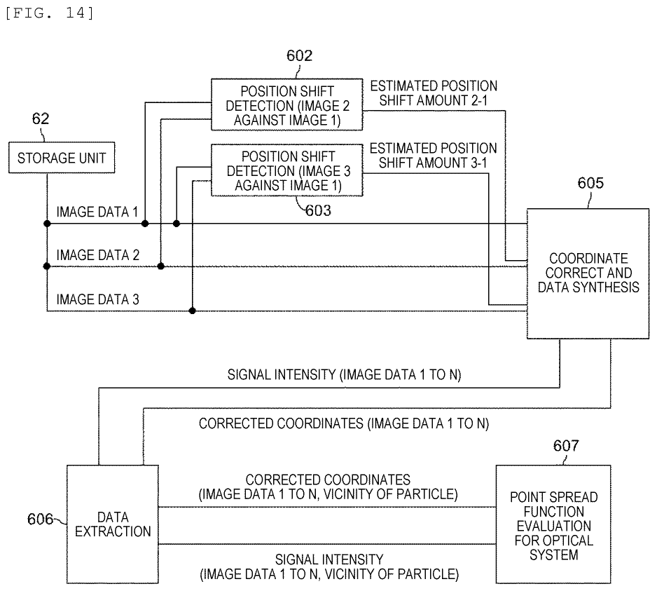

FIG. 10 is an illustrative diagram illustrating a principle of measuring a height variation in the sample surface by the height measuring unit 8 illustrated in FIG. 1. FIG. 10 illustrates a case where the sample W is shifted by Δn in the normal direction of the sample surface. In FIG. 10, the condenser lens 81 is not illustrated.

Specular reflection light of the illumination light obliquely incident on the sample W at an elevation angle θ is incident on the two-dimensional sensor 83 via the image forming lens 82. Therefore, when the height of the sample W changes from a position indicated by a broken line to a position indicated by a solid line, a trajectory of the specular reflection light is subjected to a translational movement, and an incident position of the specular reflection light on the two-dimensional sensor 83 changes. In the two-dimensional sensor 83, an electrical signal from the pixel on which the specular reflection light is incident, that is, an electrical signal corresponding to the incident position of the specular reflection light is output from the two-dimensional sensor 83. The incident position of the specular reflection light at the time when the illumination spot 40 on the sample W is at a reference height (when the height variation Δn=0) is set as a reference position. As the height of the sample surface varies, an incident position of the illumination spot 40 on the sample surface is displaced from the reference position. A height variation amount of the sample surface at the position of the illumination spot 40 can be measured from the displacement amount. The two-dimensional sensor 83 can be replaced by a one-dimensional sensor (linear sensor) in which pixels are arranged in a direction of movement of the incident position of the specular reflection light due to height variation.

Returning to the description of FIG. 1. The signal processing device 6 is a computer that processes detection signals received from the image sensors 5b, 5-0, 5-1, etc., and includes a read only memory (ROM), a random access memory (RAM), other memories, a CPU, a field-programmable gate array (FPGA), a timer, and the like.

The signal processing device 6 is assumed to be implemented by a single computer that forms a unit with a device main body (a stage, an illumination optical system, a detection optical system, an image sensor, and the like) of the defect inspection device 100 as an example, and may be implemented by a plurality of computers. In this case, a server may be used as one of the plurality of computers. This is an example in which the server is provided as a component of the defect inspection device 100. For example, a configuration may be adopted in which a computer attached to the device main body acquires a detection signal of a defect from the device main body, processes detection data as necessary, and transmits the processed detection data to a server, and the server performs processing such as defect detection and classification.

The signal processing device 6 includes a sub-pixel interpolation processing unit 61, a storage unit (memory) 62, a signal integration unit 63, and a defect detection unit 64. The sub-pixel interpolation processing unit 61, the signal integration unit 63, and the defect detection unit 64 may be implemented by hardware such as an FPGA circuit or may be implemented by a software program. At least a part of these functions of the signal processing device 6 (particularly, processing in a downstream process) can also be executed by a graphics processing unit (GPU) or a CPU mounted on the server.

The sub-pixel interpolation processing unit 61 analyzes the position of the illumination spot 40 from the detection signals of the image sensors 5b, 5-1, 5-2, etc. The storage unit 62 stores detection signals (digital data) received from the image sensors 5b, 5-1, 5-2, etc., position data calculated by the sub-pixel interpolation processing unit 61, and the like, and accumulates the detection signals and the position data as scattered light data. Based on the scattered light data accumulated in the storage unit 62, the signal integration unit 63 performs integration calculation on a plurality of pieces of scattered light data output from the same sensor and indicating different positions of the illumination spot 40, and performs integration calculation on pieces of scattered light data subjected to similar integration calculation for different image sensors. Based on the scattered light data after the integration calculation, the defect detection unit 64 extracts a portion having a high frequency and high luminance on the sample surface as a defect (performs defect inspection).

To describe the processing of the signal integration unit 63, the signal integration unit 63 adds up scattered light intensities using pieces of data obtained by scanning at different positions in the longitudinal direction in the linear illumination spot 40 for the same coordinates on the sample surface. That is, in a case where the sample W is spirally scanned, when the coordinates on the sample surface are represented by an rθ coordinate system, the scattered light intensities of the same coordinates are added up using pieces of the scattered light data having the same θ coordinate and different r coordinates. The r coordinate in the rθ coordinate system is a radial direction coordinate on the sample surface, and the θ coordinate is an azimuth coordinate on the sample surface, which is different in concept from the elevation angle θ in FIG. 10. Even in the scattered light data output from the same sensor, among pieces of data having different r coordinates, an image forming position of the scattered light from the same coordinate (that is, the pixel that receives the scattered light from the same coordinate) is displaced according to a movement amount of the sample stage ST1 during one rotation of the sample W. The movement amount of the sample stage ST1 per rotation is smaller than the beam width L1 illustrated in FIG. 4. Therefore, based on the movement amount of the sample stage ST1, a correspondence relationship between pixels serving as output sources of the signals to be added up as the scattered light intensities of the same coordinates is calculated.

The control device 71 is a computer that integrally controls the defect inspection device 100, and similarly to the signal processing device 6, includes a CPU, an FPGA, a timer, and the like in addition to a ROM, a RAM, and other memories. The control device 71 is connected to the user interface 72, the monitor 73, and the signal processing device 6 in a wired or wireless manner.

The configuration is not limited thereto, and the functions of the signal processing device 6 may be mounted on the control device 71, and the control device 71 may also serve as the signal processing device 6. The user interface 72 is a device through which a user inputs various operations, and various input devices such as a keyboard, a mouse, and a touch panel can be adopted as appropriate. As the monitor 73, various display devices such as a liquid crystal display can be appropriately adopted.

The output of the height measuring unit 8, an encoder of the rotation stage and the translation stage, inspection conditions received from the user interface 72 according to an operation of an operator, and the like are received by the control device 71. The inspection conditions include, for example, a type, a size, a shape, a material, an illumination condition, and a detection condition of the sample W.

Further, the control device 71 outputs a signal for commanding operations of the actuator 9, the detection optical systems 4-0, 4-1, etc., the stage ST, and the illumination optical system 3 according to the height variation of the sample W and the inspection conditions, and outputs coordinate data of the illumination spot 40 synchronized with a defect detection signal to the signal processing device 6. The control device 71 also displays and outputs a defect inspection result obtained by the signal processing device 6 on the monitor 73.

FIG. 11 is a schematic diagram of a three-dimensional arrangement of the sample W and the inclined optical system. The optical axis OA2 of each of the detection optical systems 4-1, etc. is inclined by an angle θ with respect to the normal line (normal direction n) to the sample W. Projection of the optical axis OA2 on the sample surface is inclined by an angle with respect to the major axis (direction S2) of the illumination spot 40. In the specification of the present application, θ described below represents the inclination angle of the optical axis OA2 in the inclined optical system with respect to the normal line n to the sample surface, and is different in concept from θ representing the elevation angle of the illumination light in FIG. 10 and θ of the above-described rθ coordinate system.

When the optical axis OA2 of the detection optical systems 4-1, etc. is inclined by the angle θ with respect to the normal line to the sample W and the projection of the optical axis OA2 on the sample surface is inclined by the angle φ with respect to the major axis of the illumination spot 40, a vector v0 of the optical axis OA2 in a three-dimensional space is expressed by the following equation (1).

$$\begin{matrix}[ Math . 1 ] & \\ {v}_{0} = ( sin θ \cdot sin φ , sin θ \cdot cos φ \cdot cos θ ) & ( 1 )\end{matrix}$$

An angle α formed by the vector v0 and a vector v2 (direction S2) of the major axis of the illumination spot 40 is obtained by equation (2).

$$\begin{matrix}[ Math . 2 ] & \\ α = arc cos ( sin θ \cdot cos φ ) & ( 2 )\end{matrix}$$

Under the condition that the height of the sample surface is at the reference position (Δn=0), the optical image OI of the illumination spot 40 falls within the light receiving surface of the image sensors 5-1, etc. without the need to correct the optical system or sensor position. Assuming that a length of the major axis of the illumination spot 40 is 2L, a difference of Δz expressed by equation (3) occurs in a working distance (a distance between the sample W and the detection optical systems 4-1, etc.) at a center of a visual field and a point separated from the center of the visual field by a distance x on the sample surface.

$$\begin{matrix}[ Math . 3 ] & \\ Δ z = x ( sin θ \cdot cos φ ) , \vert x \vert < L & ( 3 )\end{matrix}$$

An image forming magnification M is determined by the condenser lens 411 and the image forming lens 435. When the image forming magnification M is used, a position of the optical image OI on the light receiving surface of the image sensors 5-1, etc. at a point separated from the center of the visual field by the distance x on the sample surface is expressed by equation (4).

$$\begin{matrix}[ Math . 4 ] & \\ Δz = {M}^{2} x ( sin θ \cdot cos φ ) , \vert x \vert < L & ( 4 )\end{matrix}$$

In general, the line sensor is disposed such that the light receiving surface is orthogonal to a center line (optical axis) of a beam emitted from the image forming lens. On the other hand, in the embodiment, as illustrated in FIG. 6, the light receiving surfaces of the image sensors 5-1, etc. are inclined with respect to the optical axis OA2, and an optical image without defocus is detected regardless of the difference Δz in the working distance occurring in the visual fields of the detection optical systems 4-1, etc. that are inclined optical systems.

A vector v1 of the major axis (center line extending in the longitudinal direction) of the light receiving surface illustrated in FIG. 6 is set such that the vector v1 is included in the same plane together with the vector v2 (direction S2) of the major axis of the illumination spot 40 and the vector v0 of the optical axis OA2, and an angle β with respect to the vector v0 satisfies equation (5).

$$\begin{matrix}[ Math . 5 ] & \\ tan α = M \cdot tan β & ( 5 )\end{matrix}$$

At this time, the angle α formed by the vectors v0 and v2 satisfies a relationship of equation (6).

$$\begin{matrix}[ Math . 6 ] & \\ cos α = sin θ \cdot cos φ & ( 6 )\end{matrix}$$

When the image forming magnification M increases, the angle β formed by the vectors v0 and v1 decreases from equation (5), and an incident angle of the reflected light with respect to the image sensor 5-1 increases. When the image forming magnification M is increased to 2, the scattered light is incident on the image sensor 5-1 at an incident angle close to 90 degrees at the maximum. However, since transmittance of an antireflection film formed on the light receiving surface of the image sensor 5-1 depends on the incident angle of the light beam, and at an incident angle close to 90 degrees, the transmittance decreases and light receiving sensitivity of the image sensor 5-1 decreases, the image forming magnification M may be set to two times or less.

When polarization of illumination applied to a defect and a substrate surface changes, the intensity and polarization of the scattered light from the defect and the substrate surface change. As a result, an intensity ratio of the scattered light from the defect and the substrate surface detected by the image sensors 5-1, 5-2, etc. of the detection optical systems 4-0, 4-1, etc. changes, and thus the defect detection performance changes.

In the defect inspection device 100 according to the embodiment, a point spread function (PSF)) is measured in order to adjust the focus of the detection optical systems 4-0, 4-1, 4-2, etc. The point spread function refers to an intensity distribution of a detection image (point image) of a particulate minute object on the sample surface detected by the detection optical systems 4-0, 4-1, 4-2, etc. The focus adjustment of the detection optical systems 4-0, 4-1, 4-2, etc. is performed by measuring a peak intensity or a spread width of the measured point spread function and maximizing the peak intensity or minimizing the spread width.

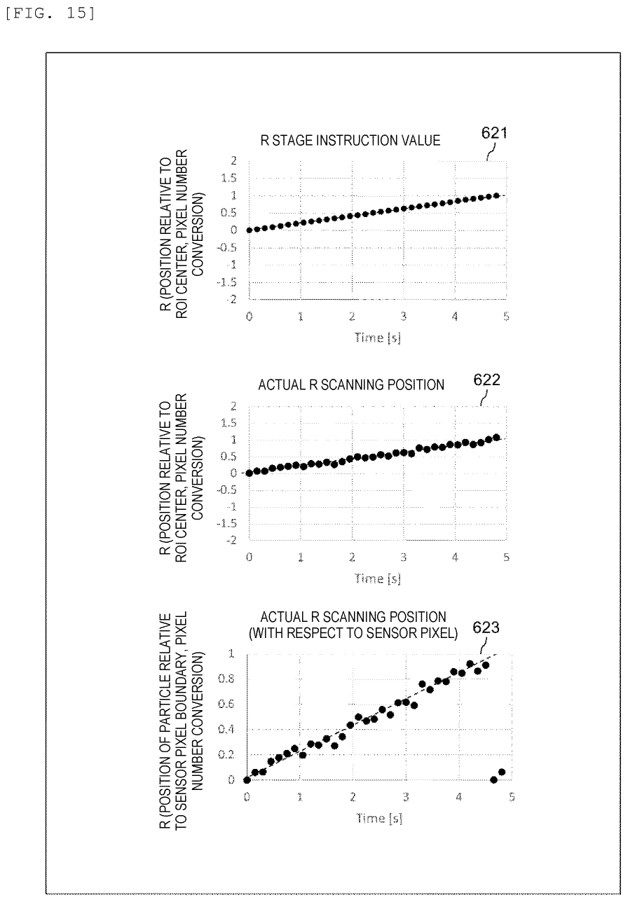

FIG. 12 is a diagram illustrating a standard particle dispersed sample (wafer on which standard particles are dispersed) and a scanning trajectory for measuring a point spread function of each detection optical system. FIG. 13 is a diagram illustrating a functional block of the signal processing device that acquires a point spread function from a region ROI.

Standard particles having a uniform particle diameter are dispersed by an atomizer on a surface of a standard particle dispersed sample W1. The standard particles are particulate objects having a particle diameter smaller than a wavelength of the illumination light. A plurality of (6 in FIG. 12) circular regions on the standard particle dispersed sample W1 are standard particle dispersed regions W2. The standard particle dispersed regions W2 have a diameter of about 30 mm and are arranged at the same radial position on the sample surface at predetermined intervals in a circumferential direction. In the dispersed regions W2, predetermined regions of interest ROI having the same r coordinate and including a plurality of standard particles are set, respectively. The region of interest ROI scanned when measuring the point spread function can be selected for each of the detection optical systems 4-0, 4-1, 4-2, etc. This is because the particle diameter of the standard particle suitable for measuring the point spread function varies depending on the position and sensitivity of the detection optical systems 4-0, 4-1, 4-2, etc. with respect to the illumination spot 40.

When estimating the point spread function, the standard particle dispersed sample W1 is set on the stage ST, the control device 71 commands the stage ST to control a scanning trajectory TR of the illumination spot 40 so as to scan each region of interest ROI a plurality of times, and detection signals (signal intensity and coordinate data) thus obtained for the plurality of scans are recorded in the storage unit 62. At this time, since the standard particle dispersed sample W1 is moved without stopping, that is, the standard particle dispersed sample W1 is scanned, the same condition as the illumination condition at the time of defect inspection can be adopted, and for example, the intensity of the illumination light emitted by the laser light source 31 can be set to 1 W or more. The detection signals stored in the storage unit 62 are scanning data for a plurality of scans (for a plurality of scanning trajectories) for the region of interest ROI selected for each of the detection optical systems 4-0, 4-1, 4-2, etc. Each scanning trajectory TR of the plurality of scans has a shift amount that is a non-integer multiple of a pixel pitch of the image sensors of the detection optical systems 4-0, 4-1, 4-2, etc.

The sub-pixel interpolation processing unit 61 estimates intensity distributions of detection signals of the same object in the region of interest ROI in a plurality of scans, and detects the shift amount of the scanning trajectory TR between the plurality of scans based on the intensity distributions. Further, the sub-pixel interpolation processing unit 61 aligns and synthesizes the intensity distributions in the plurality of scans based on the detected shift amount of the scanning trajectory TR, and acquires the point spread function related to the object. Since the obtained point spread function is obtained by synthesizing the intensity distributions in which the scanning trajectory TR is shifted by a non-integer multiple of the pixel pitch of the image sensor, the obtained point spread function is a high-resolution sub-pixel interpolation signal with a data interval smaller than the pixel pitch of the image sensors of the detection optical systems 4-0, 4-1, 4-2, etc. and in sub-pixel units.

When the point spread function serving as the sub-pixel interpolation signal is obtained, the focus adjustment of the detection optical systems is performed based on the point spread function. The point spread function obtained for the detection optical system 4-1 is used to calibrate the focus of the detection optical system 4-1, and the point spread function obtained for the detection optical system 4-2 is used to calibrate the focus of the detection optical system 4-2. Specifically, the point spread function is evaluated (a peak value and the spread width are calculated), and the focus of the detection optical system is adjusted in a case where the evaluation value does not satisfy a predetermined condition, for example, a case where the peak value is equal to or less than a predetermined threshold, a case where the spread width is equal to or more than a predetermined threshold, or in both cases. The focus adjustment can be performed by the control device 71 calculating a correction amount based on the condition at the time of the point spread function and commanding a corresponding actuator of the defect inspection device 100, or can be manually performed based on the obtained data. For example, the focus is finely adjusted by controlling an actuator (for example, the actuator 9) that adjusts the height, angle, or the like of the detection optical system or the image sensor. In this way, the focus of the detection optical system is adjusted so that the evaluation of the point spread function satisfies the above conditions, for example, the peak value is larger than the predetermined threshold, the spread width is smaller than the predetermined threshold, or both conditions are satisfied.

In addition, as the focus adjustment of the detection optical system, for example, an example is also conceivable in which the peak intensity or the spread width is measured for each of a plurality of point spread functions measured by changing an adjustment state of the detection optical system, and the adjustment state in which the peak intensity of the point spread function is the maximum or the spread width of the point spread function is the minimum is adopted.

When the focus adjustment of each detection optical system is completed as necessary in such a manner, the defect inspection device 100 executes the defect inspection of the sample W according to an inspection command.

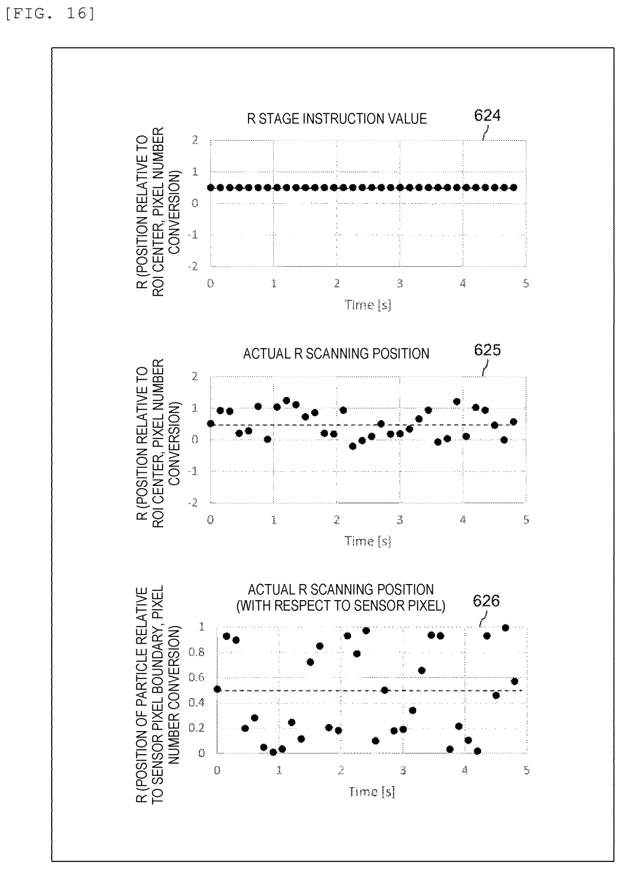

FIG. 14 is a block diagram illustrating processing content related to the estimation of the point spread function mainly performed by the sub-pixel interpolation processing unit 61 of the signal processing device 6. In the description of FIG. 14, although an example of estimating the point spread function from the detection signal of the detection optical system 4-1 will be described, the processing of estimating the point spread function from the detection signal of another detection optical system is the same.

First, a selected region of interest ROI is scanned a plurality of times, and image data (array of signal intensities) for each scan output from the detection optical system 4-1 is extracted from the storage unit 62. N sets of image data 1 to N of the region of interest ROI obtained by N scans are to be processed. In FIG. 14, only three sets of image data, image data 1, image data 2, and image data 3, are shown.

In processing of position shift amount detection 602 and 603, one set (image data 1) of N sets of images is set as a reference image, and position shift amounts of the other image data (image data 2, 3, . . . , N) with respect to the reference image are detected as estimated position shift amounts 2−1, 3−1, . . . , and N−1 based on the intensity distribution of the detection signal.

In processing of coordinate correction and data synthesis 605, coordinate values (array of coordinate values) corresponding to the image data 2 (array of intensities) are corrected using the estimated position shift amount 2−1. Similarly, coordinate values (array of coordinate values) corresponding to image data i (array of intensities) are corrected using an estimated position shift amount i−1 (i=2, 3, . . . , N) (coordinate correction). Coordinates of the image data 1 to N and corrected coordinates corresponding to the image data 1 to N are combined into one array (data synthesis).

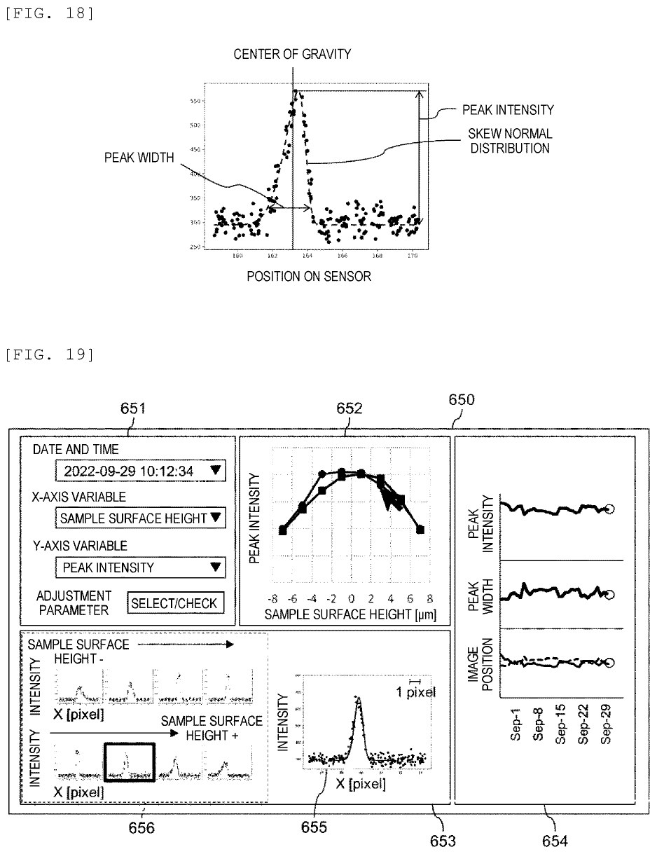

By the above processing, a high-resolution point spread function (sub-pixel interpolation data) by N scans in which the scanning trajectory TR is shifted in sub-pixel units is obtained. A principle of the processing in FIG. 14 will be described later in detail reference to FIG. 17. Processing of data extraction 606 is executed for data in the vicinity of a specific particle (for example, particle a in FIG. 17) from the obtained sub-pixel interpolation data, and processing of point spread function (PSF) evaluation 607 of the optical system is executed for each particle detection signal.

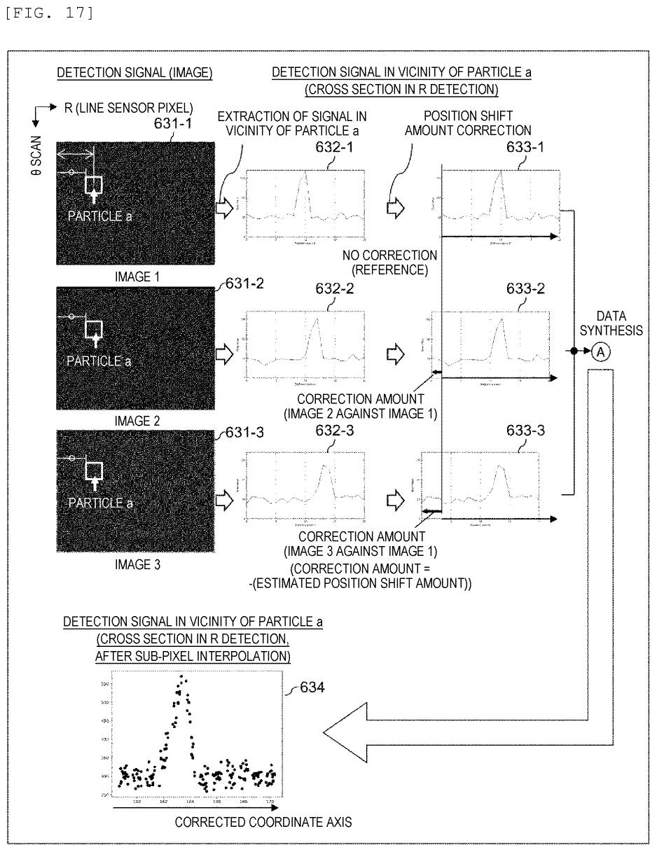

FIG. 15 is a graph illustrating an example of setting and operation for stage scanning. As described above, a plurality of sets of detection signals are stored by scanning the region of interest ROI including a plurality of particles a plurality of times. At this time, the scanning trajectory is shifted by a non-integer multiple of the sensor pixel size in the plurality of scans. In the example in FIG. 15, a case where scanning accuracy in an R direction is high, that is, a case where actual position accuracy in the R direction of the stage ST at the time of the repeated rotation operation when scanning the region of interest ROI is equal to or less than 1 pitch of pixels of the sensor of the detection optical system even including an error with respect to an instruction value of an R position with respect to the stage ST is considered. In this case, when N repeated rotation scans are performed, as illustrated in an upper graph 621, for example, the stage instruction value in the R direction is increased by 1/N of 1 pixel for each rotation. Then, the stage instruction value in the R direction is shifted by 1 pixel during N rotations. When the scanning accuracy is high as described above, in each of a plurality of scans of the region of interest ROI, the control device 71 changes the stage instruction value in the R direction for the stage ST to generate the shift amount of the scanning trajectory TR. In this case, although an error may occur with respect to the R stage instruction value, as illustrated in a middle graph 622 and a lower graph 623, object passage positions in the R direction in the pixel are evenly distributed at an interval of a non-integer multiple (approximately 1/N times) of a pixel interval.

FIG. 16 is a graph illustrating another example of setting and operation for stage scanning. Also in this example, an interval of the scanning positions in a plurality of scans is set to be a non-integer multiple of the pixel size. However, in this example, a case where the scanning accuracy in the R direction is low, that is, a case where the actual position accuracy in the R direction of the stage ST at the time of the repetitive rotation operation when scanning the region of interest ROI varies randomly beyond 1 pitch of the pixels of the sensor of the detection optical system with respect to the instruction value of the R position with respect to the stage ST will be considered. In this case, it is not necessary to shift the R stage instruction value by a width narrower than the pixel pitch for each rotation, and for example, as illustrated in an upper graph 624, the R stage instruction value may be fixed to a constant value. By using the fact that the actual stage position randomly varies for each rotation, the scanning trajectory TR can be shifted by a non-integer multiple of the pixel interval for each scan as illustrated in a middle graph 625 and a lower graph 626.

FIG. 17 is an illustrative diagram of the principle of the sub-pixel interpolation processing schematically illustrated in FIG. 14. Image data 1 to 3 (631-1 to 631-3) and cross-sectional waveform data (graphs 632-1 to 632-3) illustrated in FIG. 17 are data created by simulation using a PC assuming the width of the illumination spot 40 on the sample by the illumination optical system 3, the point spread function (PSF) of the detection optical system, and random noise. In the simulation, the number N of scans is 16, but only the image data 1 to 3 is illustrated in FIG. 17.

In the sub-pixel interpolation processing, first, image data for N scans including the image data 1 to 3 (631-1 to 631-3) is read from the storage unit 62. Here, for convenience of description, attention is paid to one (particle a) of a plurality of particles included in the image data 1 to 3.

The graphs 632-1 to 632-3 show estimated intensity distributions in the R direction of the detection signal of the particle a. A horizontal axis of the graphs 632-1 ot 632-3 corresponds to a pixel number (R direction) of the image sensor. By the plurality of scans in which the scanning trajectory TR illustrated in FIGS. 15 and 16 is shifted, the positions in the R direction of signal intensity distributions in the graphs 632-1 to 632-3 are shifted from each other. The shift amount, specifically, an estimated value of the shift amount of another image (image data 2, 3) with respect to the reference image (for example, image data 1) is calculated by the processing of the position shift amount detection 602 and 603. The shift amount of the signal intensity distribution of the graphs 632-1 to 632-3 is estimated using an image registration (alignment) method in sub-pixel units, for example, a phase only correlation method. In order to obtain the accuracy of the position shift amount detection, each image data 1 to 3 preferably includes a plurality of detection signals of the same particle. If the position shift amount detection is performed by comparing images 1 to 3 in a state in which there is only a signal of a single particle in each of the images 1 to 3, it is difficult to distinguish between an intensity distribution variation due to random noise and an intensity distribution variation due to the position shift amount, which leads to underestimation of the spread width of the detection image. As the number of particles included in the image data 1 to 3 increases, the influence of an error due to random noise is reduced.

Graphs 633-1 to 633-3 are obtained by shifting positions of the graphs in the horizontal axis direction using the estimated position shift amounts obtained by the position shift amount detection as correction amounts and aligning the positions of the estimated intensity distributions of the detection signals of the image data 1 to 3. Since the correction amount is a non-integer multiple of the pixel pitch, positions of data points in the graphs 633-1 to 633-3 are shifted in sub-pixel units. A graph 634 is a single graph obtained by superimposing the data points of graphs 633-1 to 633-3.

If the estimated position shift amount is correct, it is considered that the particles in the horizontal axis direction are aligned in the graphs 633-1 to 633-3, and the position shift amount in the horizontal axis direction of the graphs 633-1 to 633-3 directly corresponds to the position shift amount in the R direction of the scanning trajectory TR in the plurality of scans. Therefore, the graph 634 is a graph obtained by correction to the position shift amount in the R direction during scanning and superimposition. Since the position shift amount in the plurality of scans is a non-integer multiple of the pixel interval, the data interval of the superimposed signals is a sub-pixel interval smaller than original data intervals of the detection signals (graphs 633-1 to 633-3) of the particle. That is, data (sub-pixel interpolation data) acquired at sampling intervals smaller than those of the original images is obtained from the plurality of pieces of image data. In the above procedure, the correction of the position shift is performed based on the obtained image data, and thus can be performed regardless of the operation accuracy of the stage ST.

When the data interval is sufficiently small, a waveform detected as the sub-pixel interpolation data by the principle illustrated with reference to FIG. 17 ideally approximates a waveform (a waveform on which a blur corresponding to a width of a detection pixel is superimposed) obtained by convolving a spatial response function (a rectangular pulse waveform with the detection pixel width) per detection pixel with respect to an intensity signal waveform of a detection lens. Therefore, by performing deconvolution processing using the rectangular pulse waveform with the detection pixel width on the waveform obtained by the sub-pixel interpolation, the point spread function of the detection optical system with high resolution excluding the roughness of the data interval due to the pixel interval of the image sensor and the blur due to the pixel size is obtained. By using this point spread function, the evaluation of a state of blurring of the detection optical system and the measurement of a focus shift based on the evaluation can be performed with high accuracy. Although the same deconvolution processing can be performed on the original signal waveform on which the sub-pixel interpolation is not performed, in this case, a slight noise of the detection intensity greatly affects the processed waveform, and it is difficult to perform reliable evaluation.

In the case of the configuration of the defect inspection device 100 according to the embodiment, the intensity distribution of the illumination spot 40 appears as a detection signal intensity waveform in a θ direction. A data interval thereof is determined by a line rate of the image sensor, and corresponds to a θ direction sampling interval on the sample determined by the product of a time interval thereof and a θ direction scanning speed for the sample. Although the estimation of the sub-pixel interpolation signal in the R direction has been described with reference to FIGS. 14 and 15, the same processing may be performed for the θ direction to estimate a two-dimensional sub-pixel interpolation signal in the R direction and the 0 direction. A position shift amount of a sampling point in the θ direction can be implemented by shifting a coordinate output timing of the sensor with respect to the encoder of the rotation stage in addition to a variation in the operation of the stage ST in a rotation direction.

In this case, the calculation of the estimated position shift amounts 2−1 and 3−1 described with reference to FIG. 14 is performed for both the R direction and the θ direction to obtain the respective estimated position shift amounts. Although the relationship between the instruction value and the error amount of the stage scanning illustrated in FIGS. 15 and 16 has been described for the R direction, for the θ direction as well, an object position shift amount in the θ direction for each rotation is set to be non-equal to the pixel interval by the configuration and setting illustrated in any of FIGS. 15 and 16. In the sub-pixel interpolation signal estimation in FIG. 17, two-dimensional position shift correction is performed using position shift amount estimated values in the R and θ directions to obtain two-dimensional signal intensity waveform (image) data subjected to sub-pixel interpolation.

FIG. 18 is a graph illustrating a method of calculating an evaluation value for evaluating a state of the optical system from the obtained signal intensity waveform data, that is, the point spread function data. This processing is performed as the processing of the point spread function evaluation 607 (FIG. 14) of the optical system. Target data may be sub-pixel interpolation data or data obtained by performing deconvolution processing on the sub-pixel interpolation data. The processing is performed by applying a function to the signal intensity waveform by the least squares method or the like and evaluating parameters thereof. An evaluation value from a point spread function waveform is calculated. As the evaluation value for evaluating the point spread function, for example, a peak intensity (the maximum value of the signal intensity), a peak width (the spread width of the distribution), or an image position (a centroid position of the distribution or a position obtained by applying a function to be described later) can be calculated. As described above, for example, when the peak intensity is used as the evaluation value, the detection optical system is adjusted such that the peak intensity is larger than a predetermined threshold. As the function to be applied, a Gaussian distribution function, a concave quadratic function, an Airy pattern (the square of the Bessel function of the first kind), or the like is used. By applying the function, the influence of noise is reduced, and a stable evaluation value is obtained.

Further, in the detection optical systems 4-1, 4-2, etc., since the light receiving surface of the image sensor is inclined with respect to a detection optical axis, the spread of the image due to defocus when the light receiving surface of the image sensor is shifted in a detection optical axis direction is left-right asymmetric. In order to apply a corresponding function to a left-right asymmetric waveform, a skew normal distribution having a left-right asymmetric shape is used. The skew normal distribution f(x) is expressed by equations (10) to (12). A degree of left-right asymmetry is given by skewness α in addition to (a value proportional to) a peak intensity A, a spread width σ, and a position x0. In the example in FIG. 18, the skew normal distribution of α=−1.5 is represented by a dotted line.

$$\begin{matrix}[ Math . 7 ] & \\ A cos ( 2 π x / 90 ) + B sin ( 2 π x / 90 ) + C & ( 7 )\end{matrix}$$

$$\begin{matrix}[ Math . 8 ] & \\ A sin ( 2 π ( x - B ) / 90 ) + C & ( 8 )\end{matrix}$$

Here, x is a wavelength plate angle set value.

$$\begin{matrix}[ Math . 9 ] & \\ P = λ / sin {θ}_{i} & ( 9 )\end{matrix}$$

$$\begin{matrix}[ Math . 10 ] & \\ ϕ ( x ) = \frac{1}{\sqrt{2 π}} {e}^{- \frac{{x}^{2}}{2}} & ( 10 )\end{matrix}$$

$$\begin{matrix}[ Math . 11 ] & \\ Φ ( x ) = \frac{1}{2} [ 1 + erf ( \frac{x}{\sqrt{2}} ) ] & ( 11 )\end{matrix}$$

$$\begin{matrix}[ Math . 12 ] & \\ f ( x ) = \frac{2}{σ} A ϕ ( \frac{x - {x}_{0}}{σ} ) Φ ( α \frac{x - {x}_{0}}{σ} ) & ( 12 )\end{matrix}$$

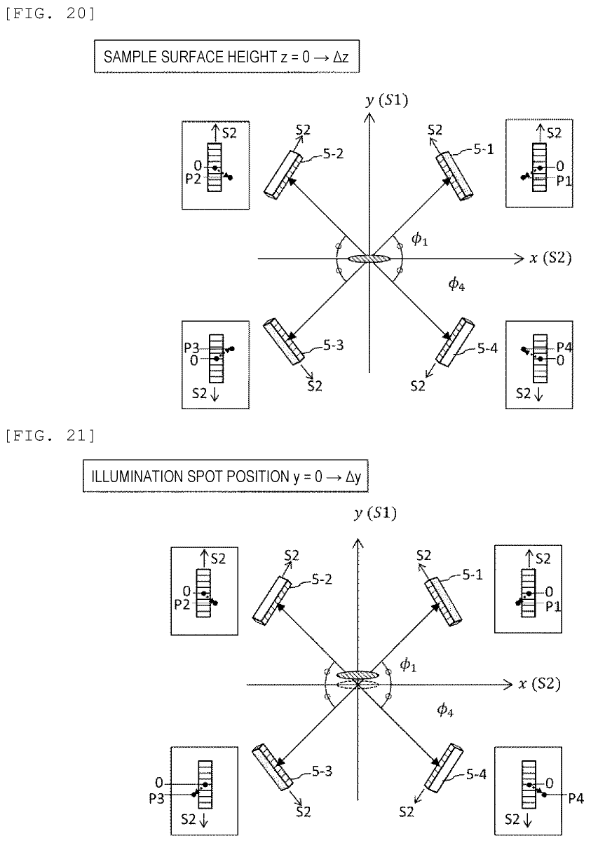

FIG. 19 is a schematic diagram of a GUI screen for checking a point spread function measurement result of the detection optical system in the invention. In a data selection portion 651 in a GUI screen 650, an acquisition date and time of measurement data is selected, and a parameter to be displayed is selected. In the data selection portion 651, it is possible to check, narrow down, and select another adjustment parameter that is not displayed in the drawing. Examples of the adjustment parameter include the position of the illumination spot, the position of the image sensor, or a setting instruction value for a movable portion of the device main body of the defect inspection device that affects the position of the illumination spot or image sensor. FIG. 19 illustrates an example in which the stage ST is driven in a height direction (Z direction) to scan the height of the sample surface, and a result of evaluating the peak intensity is displayed. By selecting the height of the sample surface as an X-axis variable and the peak intensity as a Y-axis variable, a graph of the dependency of the peak intensity on the height of the sample surface is displayed in a graph display portion 652.

In the example in FIG. 19, data of two detection optical systems is superimposed and displayed in the graph display portion 652. When one adjustment state (in this example, a state of the height of one sample surface) is selected in the data selection portion 651 or the graph display portion 652 in combination therewith, measurement data 655 of the point spread function in that state is displayed in a right part of a point spread function display portion 653. A series of data 656 acquired by scanning the height of the sample surface is also displayed on a left part of the point spread function display portion 653, and it is also possible to select one adjustment state therefrom and display the measurement data 655. In this way, the sub-pixel interpolation data acquired and processed by the above method is displayed in the point spread function display portion 653. An optical system state trend display portion 654 displays a temporal change in a main point spread function evaluation value, and it is possible to check from here whether an abnormality occurs in the optical system.

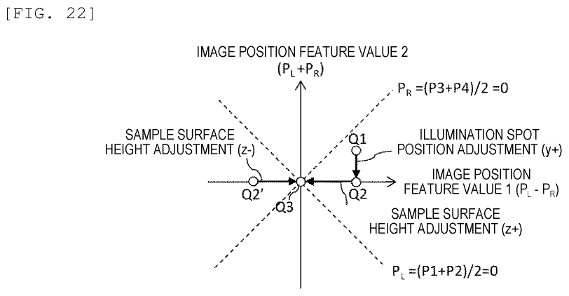

FIG. 20 is a schematic diagram illustrating a position shift direction of a point image on the image sensor due to a sample surface height shift in the invention. In this example, detection optical systems 4-1 to 4-4 are arranged in four directions (corresponding image sensors 5-1 to 5-4 are illustrated in the drawing). The detection optical systems 4-4 and 4-3 are arranged in mirror symmetry with the detection optical systems 4-1 and 4-2 with respect to a plane including the S2 direction and the normal line to the sample W. Here, positive or negative of a moving direction of the image on the image sensor is defined such that a positive direction of an S2 axis on the sample corresponds to a positive direction in any image sensor. At this time, the position shift of the point image on the image sensor due to the sample surface height shift is in the same direction in the S2 direction between the image sensors (between the image sensors 5-1 and 5-4 and between the image sensors 5-2 and 5-3) arranged the symmetrically to each other due to the symmetry of t arrangement, and position shift amounts are substantially the same. Defocus of a detection image due to the sample surface height shift is also defocus in the same direction among the four detection optical systems. Since the direction of the sample surface height shift (positive or negative of AZ) corresponds to the direction of the image position shift (positive or negative of P1 to P4), the direction of the sample surface height shift can be estimated from the direction of the image position shift. An image position shift amount is proportional to a sample surface height shift amount, and a proportional coefficient thereof is obtained by geometric calculation from an optical magnification of the detection optical system and the arrangement of the image sensor. Regarding a method of searching for a condition in which the peak intensity is maximized by changing the height of the sample surface several times to adjust the focus state of the optical system, it takes time to acquire data. On the other hand, since the estimation of the sample surface height shift based on the sign and amount of the image position shift can be performed only by a measurement value in a certain sample surface height state, there is an advantage that the required time is short.

FIG. 21 is a schematic diagram illustrating a position shift direction of a point image on the image sensor due to an illumination spot position shift (S1 direction) in the invention. Since the illumination spot position shift is in a direction orthogonal to a reference plane of the mirror-symmetry described above, the position shift of the point image on the image sensor due to the illumination spot position shift is in opposite directions in the S2 direction between the symmetrically arranged sensors (between the image sensors 5-1 and 5-4 and between the image sensors 5-2 and 5-3), and shift amounts are substantially the same. Defocus of the detection image due to the illumination spot position shift is also in opposite directions between the sensors arranged symmetrically to each other. Similar to the estimation of the direction and amount of the sample surface height shift described with reference to FIG. 20, the direction and amount of a beam position shift can be estimated from the direction and amount of the image position shift.

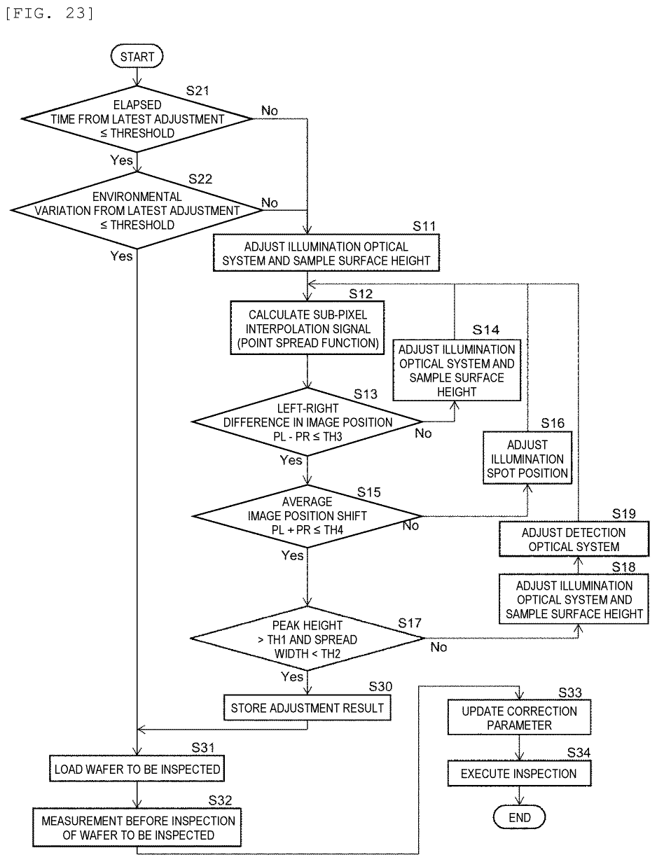

FIG. 22 is a diagram illustrating an example of a method of adjusting an illumination optical system and a detection optical system according to the invention. In FIGS. 20 and 21, an average of the position shifts (P1, P2) of the detection images in the image sensors 5-1 and 5-2 of the detection optical systems in the first quadrant and the second quadrant is denoted by P_{L}, and an average of the position shifts (P3, P4) of the detection images in the image sensors 5-3 and 5-4 of the detection optical systems in the third quadrant and the fourth quadrant is denoted by P_{R}. A reference of the position shift is a value (an average of a plurality of particles on the standard particle dispersed sample W) obtained by measuring the centroid position of the image on the sensor illustrated in FIG. 18 and taking a difference from a reference value recorded in a state after the adjustment of the optical system is completed, and a difference from the value is set as the position shift amount. P_{L}−P_{R} is an image position feature value 1, and P_{L}+P_{R} is an image position feature value 2. When only the sample surface height shift and the illumination spot position shift are considered as factors of adjustment shift, the image position feature value 1 corresponds to a value obtained by extracting a position shift component in a common direction from the position shifts of the plurality of image sensors, and is proportional to the sample surface height shift described with reference to FIG. 20. The image position feature value 2 corresponds to a value obtained by extracting a position shift component generated in the opposite direction between the sensors arranged symmetrically from detection image position shifts in the plurality of image sensors, and is proportional to the illumination spot position shift described with reference to FIG. 21. FIG. 22 is a diagram in which these two feature values are taken on a horizontal axis and a vertical axis, respectively, and a state without a shift from the reference corresponds to an origin. An adjustment state Q1 in FIG. 22 is shown. By estimating the illumination spot position shift and adjusting the illumination spot position by the method described with reference to FIG. 21, a state Q2 (P_{L}−P_{R}=0) in which only the sample surface height shift remains is obtained. Next, a state Q3 (P_{L}+P_{R}=0) is obtained by adjusting the height of the sample surface by the method described with reference to FIG. 20. By the above procedure, both the sample surface height shift and the illumination spot position shift are adjusted. The adjustment from Q1 to Q2 is performed based on the difference (P_{L}−P_{R}) of the position shift amounts between the image sensors in a plurality of directions, and thus is effective even when the position of the standard particle dispersed sample W in the XY plane with respect to the detection optical system at the time of the reference value measurement is not reproduced by the attachment and detachment of the standard particle dispersed sample W for adjustment.

When the cause of an adjustment error of the illumination optical system and the detection optical system is only the sample surface height shift or the illumination spot position shift, the image position shifts P1 and P2 are equal to each other and the image position shifts P3 and P4 are equal to each other due to the symmetry of the illumination and detection optical systems, and thus the adjustment is completed by the above-described procedure. The image position shift in the opposite direction between P1 and P2 and the image position shift in the opposite direction between P3 and P4 do not appear in the image position feature value 1 or the image position feature value 2, and thus remain after the above-described adjustment is completed. These shifts are not caused by the sample surface height shift or illumination spot position shift that exerts an influence symmetrically between symmetrical detection optical systems, but caused by other adjustment errors, and occur individually for each detection optical system. Specifically, since the position shift and the focus shift of the image sensor of each detection system with respect to the illumination spot position are estimated to be the cause, the adjustment is performed so as to cancel the remaining image position shifts as described above by individual adjustment of the lenses constituting the detection optical systems 4-1 to 4-4 or individual adjustment of the image sensors 5-1 to 5-4.

FIG. 23 is a flowchart illustrating an adjustment procedure of the illumination optical system and the detection optical system using the standard particle dispersed sample W1. The following procedure is executed by the signal processing device 6, the control device 71, a manual manner, or a combination thereof.

When execution of inspection on the sample W is instructed, before an inspection operation for the sample W, it is determined whether an elapsed time from the most recent adjustment (adjustment of the optical system using the standard particle dispersed sample W1 performed last in the past) is equal to or less than a predetermined threshold (step S21), and whether an environmental variation (variation in an outside air temperature, an air pressure, and an internal temperature of the device main body) from the most recent adjustment is equal to or less than a predetermined threshold (step S22). If both the determination conditions of steps S21 and S22 are satisfied (if the elapsed time and the environmental variation are equal to or less than the respective thresholds), the adjustment processing for the optical system is omitted, and inspection operations of step S17 and following steps are executed. If the determination condition of any one of steps S21 and S22 is not satisfied (if exceeding the threshold), there is a concern that a focus shift may occur due to a temporal change or an environmental variation of the optical system, and thus the procedure proceeds from any one of steps S21 and S22 to step S11 and the optical system and the height of the sample surface are readjusted.

When readjusting the optical system and the height of the sample surface, first, the illumination optical system 3 and the height of the sample surface are adjusted based on the measurement of the illumination spot by a vertical detection optical system (step S11). Next, as described with reference to FIGS. 12 to 18, the standard particle dispersed sample W1 is loaded, the standard particle dispersed sample W1 is scanned a plurality of times, a point spread function as a sub-pixel complement signal is calculated from detection signals for the plurality of scans (step S12), the point spread function is evaluated, a left-right difference in image position (the image position feature value 1 described above) is obtained from the result, and a threshold determination is performed (step S13). If the image position feature value 1 is larger than a threshold TH3, the adjustment of the sample surface height and the adjustment (focus adjustment) of the illumination optical system corresponding thereto are performed by the method described with reference to FIG. 22 (step S14). After the left-right difference in image position is adjusted to be equal to or less than the threshold TH3 by a loop of steps S12, S13, and S14, an average image position shift (the image position feature value 2 described above) is obtained, and a threshold determination is performed (step S15). If the image position feature value 2 is larger than a threshold TH4, an illumination spot position (S1 direction) is adjusted by the method described with reference to FIG. 22 (step S16). By a loop of steps S12, S15, and S16, the average image position shift is adjusted to be equal to or less than the threshold TH4. Next, it is determined whether a peak height of the point spread function is larger than a predetermined threshold TH1 and a spread width of the point spread function is smaller than a predetermined threshold TH2 (step S17), and if the determination is satisfied, the adjustment of the optical system is completed and an adjustment result is stored in the memory (step S30), and the procedure proceeds to the inspection operations of step S31 and following steps. On the contrary, it is determined that the adjustment is necessary for the detection optical system of which the peak height of the point spread function is equal to or less than the predetermined threshold TH1 or the spread width of the point spread function is larger than the predetermined threshold TH2, an adjustment state is estimated by an algorithm described with reference to FIG. 19, the adjustment of the sample surface height and the illumination optical system (step S18) and the adjustment of the detection optical system (step S19) are performed according to the estimated adjustment state, and the procedure returns to step S12. Here, since it is basically estimated that an error individually occurring for each detection optical system described with reference to FIG. 22 remains, the individual adjustment of the lenses constituting the detection optical systems 4-1 to 4-4 or the individual adjustment of the image sensors 5-1 to 5-4 is mainly performed. It is conceivable to execute the adjustment operations of steps S11 to S19 during the idling time in which the wafer to be inspected is not allocated.

Steps S31 to S34 are a procedure for executing the inspection operation on the sample W (wafer to be inspected). After the processing of loading the sample W (step S31), measurement before inspection of the sample W (step S32), and update of a correction parameter (step S33), defect inspection of the sample W is executed (step S34).

In order to avoid a variation in sensitivity due to a temporal change in the state of the device main body of the defect inspection device 100, it is desirable to periodically adjust the optical system according to the above procedures. However, since throughput of the inspection decreases (the number of wafers that can be inspected per hour decreases) when the adjustment of the optical system is excessively frequent, it is preferable to adjust the optical system, for example, once every 3 hours, once every 12 hours, or once every 24 hours. The device main body of the defect inspection device includes various sensors such as a thermometer, a barometer, and an accelerometer. It is desirable to perform the adjustment of the optical system even when an abnormality such as a temperature change, an air pressure change, or excessive vibration in the device main body is detected based on outputs of these sensors.

The invention is limited to the embodiments described above, and includes various modifications. For example, the above-described embodiments have been described in detail to facilitate understanding of the invention, and the invention is not necessarily limited to those including all the configurations described above. A part of a configuration of a certain embodiment can be replaced with a configuration of another embodiment, and a configuration of another embodiment can be added to a configuration of a certain embodiment. A part of a configuration of each embodiment may be added to, deleted from, or replaced with another configuration.

Some or all of the above configurations, functions, processing units, processing methods, and the like may be implemented by hardware such as an integrated circuit. The above configurations, functions, and the like may be implemented by software by a processor interpreting and executing a program for implementing each function. Information such as a program, a table, and a file for implementing each function can be stored in a recording device such as a memory, a hard disk, and a solid state drive (SSD) or a recording medium such as a flash memory card and a digital versatile disk (DVD).

Control lines and information lines considered to be necessary for description are shown in each embodiment, and not all control lines and information lines in a product are necessarily shown. Actually, almost all configurations may be considered to be connected.

In the above-described embodiment, a case where the invention is applied to a mode in which the stage ST is rotated and the sample is scanned in the Rθ coordinate system has been described as an example, and the invention can also be applied to a mode in which the sample is scanned in an XY orthogonal coordinate system as described with reference to FIG. 3, and the same effects can be obtained.

### REFERENCE SIGNS LIST

2-1: estimated position shift amount (shift amount)
3: illumination optical system
3-1: estimated position shift amount (shift amount)
4-0, 4-2, . . . , 4-N: detection optical system
5-0, 5-2, . . . , 5-N, 5b: image sensor
6: signal processing device
71: control device
100: defect inspection device
a: particle (object)
ROI: region of interest
ST: stage
TR: scanning trajectory
W: sample
W1: standard particle dispersed sample (sample)

1. A defect inspection device comprising:
a stage on which a sample is to be placed and moved;
an illumination optical system configured to irradiate the sample with illumination light;
a detection optical system configured to detect scattered light generated at the sample by forming an image of the scattered light on an image sensor;
a control device configured to control the stage; and
a signal processing device configured to process a signal output from the image sensor, wherein
the signal processing device
stores detection signals obtained by scanning a predetermined region of interest on a surface of the sample a plurality of times along a scanning trajectory that has a shift amount of a non-integer multiple of a pixel pitch of the image sensor,
estimates intensity distributions of the detection signals of the object in the region of interest in the plurality of scans,
detects the shift amount of the scanning trajectory based on the intensity distributions, and
aligns and synthesizes the intensity distributions in the plurality of scans based on the detected shift amount, and acquires a point spread function related to the object in a sub-pixel unit having a data interval smaller than the pixel pitch.

2. The defect inspection device according to claim 1, wherein
in each of the plurality of scans of the region of interest, the control device changes an instruction value for the stage to generate the shift amount of the scanning trajectory.

3. The defect inspection device according to claim 1, wherein
a plurality of the image sensors and a plurality of the detection optical systems are provided, and
the signal processing device calculates positions of a plurality of the point spread functions acquired by the plurality of detection optical systems, respectively, and adjusts a sample height of the stage based on the positions.

4. The defect inspection device according to claim 1, wherein
the detection of the shift amount of the scanning trajectory is performed using an image registration method in the sub-pixel unit.

5. The defect inspection device according to claim 1, wherein
the sample is a sample on which a plurality of particulate objects smaller than a wavelength of the illumination light are in the region of interest, and
each of the intensity distributions of the detection signals is based on the scattered light from the plurality of objects.

6. The defect inspection device according to claim 1, wherein
an intensity of the illumination light is 1 W or more.

7. A defect inspection method for performing defect inspection on a sample by placing and moving the sample on a stage, irradiating the sample with illumination light by an illumination optical system, detecting scattered light generated at the sample by forming an image of the scattered light on an image sensor by a detection optical system, and processing a signal output from the image sensor by a signal processing device, the method comprising:
storing detection signals obtained by scanning a predetermined region of interest on a surface of the sample a plurality of times along a scanning trajectory that has a shift amount of a non-integral multiple of a pixel pitch of the image sensor;
estimating distributions of the detection signals of the object in the region of interest in the plurality of scans;
detecting the shift amount of the scanning trajectory based on the intensity distributions;
aligning and synthesizing the intensity distributions in the plurality of scans based on the detected shift amount, and acquiring a point spread function related to the object in a sub-pixel unit having a data interval smaller than the pixel pitch; and
performing the defect inspection by adjusting a focus of the detection optical system based on the point spread function.

8. The defect inspection method according to claim 7, wherein
in each of the plurality of scans of the region of interest a plurality of times, an instruction value for the stage is changed to generate the shift amount of the scanning trajectory.

9. The defect inspection method according to claim 7, wherein
a plurality of the image sensors and a plurality of the detection optical systems are provided, and
the signal processing device calculates positions of a plurality of the point spread functions acquired by the plurality of detection optical systems, respectively, and adjusts a sample height of the stage based on the positions.

10. The defect inspection method according to claim 7, wherein
the detection of the shift amount of the scanning trajectory is performed using an image registration method in the sub-pixel unit.

11. The defect inspection method according to claim 7, wherein
the sample is a sample on which a plurality of particulate objects smaller than a wavelength of the illumination light are in the region of interest, and
each of the intensity distributions of the detection signals is obtained based on the scattered light from the plurality of objects.

12. The defect inspection method according to claim 7, wherein
an intensity of the illumination light is 1 W or more.
